(19) United States
(12) Patent Application Publication
(10) Pub. No.: US 2016/0211419 A1
(43) Pub. Date: Jul. 21, 2016

(54) SEMICONDUCTOR LIGHT EMITTING ELEMENT AND METHOD OF MANUFACTURING THE SAME

(71) Applicant: KABUSHIKI KAISHA TOSHIBA, Tokyo (JP)

(72) Inventors: Koji Kaga, Komatsu Ishikawa (JP); Hiroshi Katsuno, Komatsu Ishikawa (JP); Masakazu Sawano, Nonoichi Ishikawa (JP); Go Oike, Nomi Ishikawa (JP); Kazuyuki Miyabe, Kanazawa Ishikawa (JP)

(21) Appl. No.: 14/994,645

(22) Filed: Jan. 13, 2016

(30) Foreign Application Priority Data
Jan. 16, 2015 (JP) 2015-006647

(51) Int. Cl. H01L 33/44; H01L 33/40; H01L 33/22; H01L 33/32; H01L 33/00; H01L 33/06

(52) U.S. Cl. CPC H01L 33/44; H01L 33/007; H01L 33/06; H01L 33/22; H01L 33/32; H01L 33/405; H01L 2933/0025; H01L 2933/0016

(57) ABSTRACT

A light emitting device includes a first semiconductor layer of a first conductivity type having an upper and lower surface sides. A first portion of the first semiconductor layer is adjacent to a second portion of the first semiconductor layer. A light emitting layer is adjacent to the first portion on the under surface side. A second semiconductor layer of a second conductivity type is on the light emitting layer such that the light emitting layer is between the second semiconductor layer and the first portion. A first conductive layer electrically contacts the second portion of the first semiconductor layer on the under surface side and extends beyond an outer edge of the first semiconductor layer. A protecting layer comprising a metal is on an upper surface side of the first conductive layer. A pad electrode is on the upper surface side of the first conductive layer.

### CROSS-REFERENCE TO RELATED APPLICATION

This application is based upon and claims the benefit of priority from Japanese Patent Application No. 2015-006647, filed Jan. 16, 2015, the entire contents of which are incorporated herein by reference.

### FIELD

Embodiments described herein relate generally to a semiconductor light emitting device and a method of manufacturing the same.

### BACKGROUND

A semiconductor light emitting element, such as LED (Light Emitting Diode), comprises stacked layers. The stacked layers include a p-type semiconductor layer, a light emitting layer, and an n-type semiconductor layer. The light emitting layer is disposed between the p-type semiconductor layer and the n-type semiconductor layer. A conductive layer connects to the n-type semiconductor layer. The conductive layer may extend outward beyond the stacked layer. A pad electrode for a connecting terminal is connected to the conductive layer or formed as an integral part thereof. Also, the conductive layer may also function as a reflecting layer reflecting light emitted by the light emitting layer. The material of the conductive layer may form ohmic contacts with a nitride semiconductor material used in the stacked layers and may have a high reflectivity with respect to light emitted by the light emitting layer.

However, a natural (native) oxide film may form at the surface of such a conductive layer. Once the natural oxide film forms, electrical resistance between the pad electrode and the conductive layer could be increased. Also, when the conductive layer is exposed to chemicals or etching gas during manufacturing, the conductive layer can be corroded and the reflectivity and other characteristics could be affected.

### DESCRIPTION OF THE DRAWINGS

FIG. 1A is a cross-sectional view and FIG. 1B is a top view schematically illustrating a semiconductor light emitting element according to an embodiment.

FIGS. 2A through 2C are cross-sectional views schematically illustrating a method of manufacturing the semiconductor light emitting element according to an embodiment.

FIGS. 3A through 3C are cross-sectional views schematically illustrating a method of manufacturing the semiconductor light emitting element according to an embodiment.

FIGS. 4A and 4B are cross-sectional views schematically illustrating a method of manufacturing the semiconductor light emitting element according to an embodiment.

FIGS. 5A and 5B are cross-sectional views schematically illustrating a method of manufacturing the protecting layer according to one example embodiment.

FIGS. 6A and 6B are cross-sectional views schematically illustrating a method of manufacturing the protecting layer according to another example embodiment.

FIG. 7 is a graph depicting a variation of operating voltage (Vf) in the semiconductor light emitting layer according to examples.

FIGS. 8A and 8B are a graph illustrating change over time in the operating voltage (Vf) of the semiconductor light emitting layer according to examples.

FIG. 9 is a graph depicting a relationship between sheet resistivity and thickness of a protecting layer of the semiconductor light emitting layer according to an embodiment.

### DETAILED DESCRIPTION

Embodiments provide a semiconductor light emitting element having high electric power efficiency, and a method of manufacturing the semiconductor light emitting element.

According to an embodiment, a semiconductor light emitting device includes a first semiconductor layer of a first conductivity type (e.g., n-type). The first semiconductor layer has an upper surface side and a under surface side. A first portion of the first semiconductor layer is adjacent to a second portion of the first semiconductor layer in a first direction (e.g., a layer plane direction). A light emitting layer is adjacent to the first portion on the under surface side. A second semiconductor layer of a second conductivity type (e.g., p-type) that is opposite to the first conductivity type is on the first portion. The light emitting layer (e.g., multiple quantum well) is between the second semiconductor layer and the first portion. A first conductive layer electrically contacts the second portion of the first semiconductor layer on the under surface side. The first conductive layer extends in the first direction beyond an outer edge of the first semiconductor layer. A protecting layer is on an upper surface side of the first conductive layer. The protecting layer comprises a metal (e.g., a metal nitride, a metal oxide, a metallic layer, a metallic layer stack). A pad electrode is on the upper surface side of the first conductive layer and is electrically connected to the first conductive layer through the protecting layer.

According to another embodiment, a method of manufacturing a light emitting element includes forming a stacked layer. The stacked layer includes: a first semiconductor layer of a first conductivity type, a second semiconductor layer of a second conductivity type that is opposite to the first conductivity type, and a light emitting layer that is between the second semiconductor layer and a first portion of the first semiconductor layer. The method also includes forming an insulating layer that covers an upper surface side of the first semiconductor layer. The light emitting layer is on an under surface side of the first semiconductor layer that is opposite the upper surface side. The method also includes forming a protecting layer comprising a metal on a portion of the insulating layer. The protecting layer is on an under surface side of the insulating layer. The method also includes forming a first conductive layer that is electrically contacting a second portion of the first semiconductor layer on the under surface side of the first semiconductor layer and covering the protecting layer. The method also includes exposing an upper surface side of the insulating layer by removing a part of the first semiconductor layer, then removing a portion of the insulating layer to expose a portion of the protecting layer. The method also includes forming a pad electrode on the portion of the protecting layer. The pad electrode is electrically connected to the first conductive layer by the protecting layer.

Hereinafter, each embodiment will be described with reference to the accompanying drawings. Also, the drawings are schematic or conceptual, and the relation between the thickness and width of each portion, the size ratio of portions, and the like are not necessarily the same as those in reality. Further, identical portions may be shown with different dimensions or ratios depending on the drawings.

Also, in this disclosure and the drawings, components substantially similar to those described in regard to one drawing are marked with the same reference numerals in other drawings, and detailed description may be omitted as appropriate for repeated elements.

Also, an XYZ axis system is indicated in some figures for purposes of explanation. In various embodiments, a first conductivity type may be a p-type conductivity and a second conductivity type may be a n-type conductivity, but also, a first conductivity type may be a n-type conductivity and second conductivity type may be a p-type conductivity. In general, unless stated otherwise, either conductivity type may be adopted; however, in the following examples, a first conductivity type is taken as a n-type conductivity and a second conductivity type taken as is a p-type conductivity for convenience in explanation.

### First Embodiment

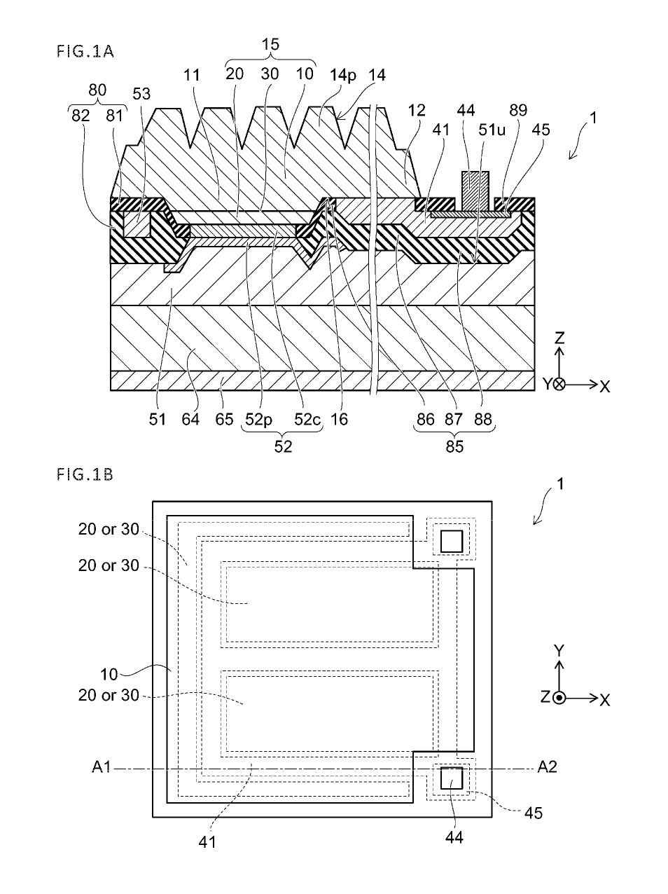

FIG. 1A is a cross-sectional view and FIG. 1B is a top view schematically illustrating a semiconductor light emitting element according to a first embodiment. FIG. 1A shows a cross section at the A1-A1 line of FIG. 1B.

FIG. 1B is a transmission schematic figure. FIG. 1B shows a transmission figure and a plane figure of the semiconductor light emitting element according to the first embodiment. An example structure, as shown in FIG. 1A and FIG. 1B, is only one example, and embodiments are not limited to this example structure.

According to this first embodiment, the semiconductor light emitting element comprises a first semiconductor layer (e.g., a semiconductor layer 10), a light emitting layer 30, a second semiconductor layer (e.g., a semiconductor layer 20), a first conductive layer (e.g., a conductive layer 41), a first layer (e.g., a protecting layer 45), and pad electrode 44.

The semiconductor layer 10 has a first surface (e.g., an upper surface 14) and a second surface (a lower surface 16) which is opposite to the upper surface 14. A conductivity type of the semiconductor layer 10 is a first conductivity type (n-type conductivity). The light emitting layer 30 is provided under the semiconductor layer 10 selectively—that is, the semiconductor layer 10 in this embodiment has a portion or portions extending beyond the light emitting layer 30 in the XY plane such that the light emitting layer 30 is not underneath (in Z direction) the entirety of semiconductor layer 10. The semiconductor layer sandwiches the light emitting layer 30 with the semiconductor layer 10. A conductivity type of the semiconductor layer 20 is a second conductivity type (a p-type conductivity). Here, the semiconductor layer 20, the light emitting layer 30 and the semiconductor layer 10 are collectively referred to as a semiconductor light emitting portion 15.

The conductive layer 41 is electrically connected to the lower surface 16 under a portion of the semiconductor layer 10 in which the light emitting layer 30 is not provided. The conductive layer 41 extends from the lower surface 16 of the semiconductor layer 10 to beyond an outer edge of the semiconductor layer 10. The protecting layer 45 is provided on at least some portions of the conductive layer 41 that are beyond the outer edge of the semiconductor layer 10. The protecting layer 45 comprises a metal. The pad electrode 44 is electrically connected to the conductive layer 41 through the protecting layer 45.

The conductive layer 41 is a layer in which a titanium (Ti) film (for example, thickness=50 nm) and an aluminum (Al) film (for example, thickness=200 nm) are stacked in this order. Also, it is possible that the conductive layer 41 is, for example, a single layer of aluminum (Al) (for example, thickness=200 nm). Also, it is possible that the conductive layer 41, for example, is a layer in which a titanium (Ti) layer (for example, thickness=50 nm) and a silver (Ag) layer (for example, thickness=200 nm) layer are stacked in this order from bottom.

The protecting layer 45 includes at least one of nickel (Ni), gold (Au), titanium (Ti) and platinum (Pt). The protecting layer 45 can be a stack of layers such as a layer comprising nickel (Ni) is stacked on a layer comprising gold (Au) or a layer comprising platinum (Pt) and a layer comprising titanium (Ti) are stacked alternately on a layer comprising gold (Au). For example, a nickel layer can be stacked on a gold layer. Or an alternating stack of platinum layers and titanium layers can be formed on a gold layer.

For example, the protecting layer 45 can be a layer in which a gold (Au) layer (for example, thickness=50 nm) and a nickel (Ni) layer (for example, thickness=10 nm) are stacked in this order.

The protecting layer 45 can be, for example, a layer in which a gold (Au) layer (for example, thickness=50 nm), a platinum (Pt) layer (for example, thickness=more than or equal to 20 nm and less than or equal to 50 nm) and a titanium (Ti) layer (for example, thickness=10 nm) are stacked in this order.

The protecting layer 45 can be, for example, a layer in which a gold (Au) layer (for example, thickness=50 nm), a platinum (Pt) layer (for example, thickness=more than or equal to 20 nm and less than or equal to 50 nm), a titanium (Ti) layer (for example, thickness=10 nm), a platinum (Pt) layer (for example, thickness=more than or equal to 20 nm and less than or equal to 50 nm) and a titanium (Ti) layer (for example, thickness=10 nm) are stacked in this order.

The protecting layer (preventing layer) 45 includes at least nitrogen or oxygen. For example, the protecting layer 45 can include titanium nitride (TiN) and be a single layer. In case the protecting layer 45 includes nitride, the thickness of the protecting layer 45 will generally be more than or equal to 50 nm, preferably, more than or equal to 100 nm. For example, in case the protecting layer 45 includes titanium nitride, the thickness of the protecting layer 45 is more than or equal to 50 nm, preferably, more than or equal to 100 nm. Also, for example, oxygen may be included in the protecting layer 45 which includes titanium nitride (for example, a titanium oxynitride material).

The insulating layer 89 is provided on the protecting layer 45. The pad electrode 44 is connected to the protecting layer 45 which exposed through an opening in the insulating layer 89.

In the semiconductor light emitting layer 1, a support substrate 64 is provided on a back surface electrode 65. The support substrate 64, when it is projected onto the X-Y plane, over laps the semiconductor layer 10 (the projected XY planar area of the support substrate is greater than to the projected XY planar area of the semiconductor layer 10). For example, a semiconductor substrate such as a silicon (Si) substrate may be used as the support substrate 64. Also, a metal layer such as copper (Cu) or copper-tungsten alloy (CuW) can be applied to the support substrate 64. Also, a plating layer (thick plating layer) can be applied to the support substrate 64. That is, the support substrate 64 could be made by a metal plating process.

The back surface electrode 65 is provided on the opposite side of the support substrate 64 from a side which the semiconductor light emitting portion 15 is disposed on the support substrate 64. For example, a stacked layer including a Ti layer, a Pt layer, and an Au layer can be used as the back surface electrode 65. Here, the Pt layer is provided between the Au layer and the support substrate 64 and the Ti layer is provided between the Pt layer and support substrate 64.

A metal layer 51 is provided on the support substrate 64. A metal, which has a low reflectivity but a high adhesion characteristic, can be provided on a side of the metal layer 51 toward the semiconductor light emitting portion 15. The high adhesion metal has high adhesion with respect to a metal layer 52, an interlayer insulating layer 80, and an interlayer insulating layer 85. For example, Ti (titanium) or TiW (titanium tungsten) can be used as the high adhesion metal. Also, for example, a stacked layer including a Ti layer, a Pt layer, and an Au layer could be used as the metal layer 51. Here, the Pt layer (platinum) is provided between the Au layer (gold) and the semiconductor light emitting portion 15 and the Ti layer (titanium) is provided between the Pt layer and the semiconductor light emitting portion 15.

Also, a connecting layer (e.g., a solder layer) could be provided between the support substrate 64 and the metal layer 51. The support substrate 64 has conductivity. The back surface electrode 65 is connected to the metal layer 51 through the support substrate 64.

The metal layer 52 is provided on the metal layer 51. The metal layer 51 is provided between support substrate 64 and the semiconductor light emitting portion 15. The support substrate 64 and the metal layer 52 are connected electrically through the metal layer 51.

The metal layer 52 is provided between the semiconductor layer 20 and the metal layer 51. The metal layer 52 includes a connecting metal portion 52c and a peripheral metal portion 52p under the connecting metal portion 52c. The metal layer 52 is a p side electrode. The metal layer 52 has a light reflective characteristic. The metal layer 52 is, for example, one of aluminum or silver.

The connecting metal portion 52c, for example, connects ohmically to the semiconductor layer 20. It is preferable that the connecting metal portion 52c has a high reflectivity for an emitted light from the light emitting layer 30. A light extracting efficiency may be improved by enhancing the reflectivity of the connecting metal portion 52c. The light extracting efficiency means here a ratio of a luminous flux which can be extracted (emitted from the device) to a total luminous flux which emitted/generated by the light emitting layer 30. The connecting metal portion 52c includes silver, for example.

The peripheral metal portion 52p, for example, covers at least a part of the connecting metal portion 52c. The peripheral metal portion 52p is electrically connected to the connecting metal portion 52c. It is preferable that the peripheral metal portion 52p also has a high reflectivity for the light emitted by the light emitting layer 30. The light extracting efficiency may be improved by enhancing the reflectivity of the peripheral metal portion 52p. The peripheral metal position 52p is, for example, silver or a silver alloy.

The semiconductor light emitting portion 15 provided on the metal layer 52. The semiconductor light emitting portion 15 comprises at least a portion which is provided on the connecting metal portion 52c. The connecting metal portion 52c contacts to the semiconductor light emitting portion 15.

In these example embodiments, a first direction (e.g., Z axis direction) is a direction which is from the metal layer 51 toward the semiconductor light emitting portion 15. Then, a direction which is perpendicular to the Z axis is the X axis direction. A direction perpendicular to both of the Z axis and the X axis is the Y axis direction. For example, the semiconductor light emitting portion 15 is disposed apart from the metal layer 51 in the Z axis direction. A shape that the metal layer 51 is projected on X-Y plane is, for example, rectangular (not specifically illustrated in figures). Also, a shape of the semiconductor light emitting portion 15 projected on X-Y plane is, for example, also rectangular. Here, projected shapes of the metal layer 51 and the semiconductor light emitting portion 15 in the X-Y plane are arbitrary and other planar projected shapes may be adopted.

The semiconductor layer 10 includes a first semiconductor portion 11 and a second semiconductor portion 12. The second semiconductor portion, in a plane that is parallel to the X-Y plan, is located adjacent to the first semiconductor portion 11. The semiconductor layer 20 is provided between the first semiconductor portion 11 and the metal layer 52 (the connecting metal portion 52c). The light emitting layer 30 is provided between the first semiconductor portion 11 and the semiconductor layer 20.

The semiconductor layer 20 is provided between the semiconductor layer 10 and the connecting metal portion 52c. The light emitting layer 30 is provided between the semiconductor layer 10 and the semiconductor layer 20.

The semiconductor layer 10, the semiconductor layer and the light emitting layer 30 include nitride semiconductor respectively. The semiconductor layer 10, the semiconductor layer 20 and the light emitting layer 30, for example, include AlₓGa_{1-x-y}In_{y}N (x≧0, y≧0, x+y≦1).

The semiconductor layer 10, for example, includes a Si doped n-type gallium nitride (GaN) contact layer and a Si doped n-type AlGaN (aluminum gallium nitride) cladding layer. The Si doped n-type AlGaN cladding layer is provided between the Si doped n-type GaN contact layer and the light emitting layer 30. Also, it is possible that the semiconductor layer 10 further includes a GaN buffer layer. The Si doped n-type GaN contact layer is provided between the GaN buffer layer and the Si doped n-type AlGaN clad layer. In this case, an opening is provided at GaN buffer layer, then, the conductive layer 41 connects with the n-type GaN contact layer through this opening.

The light emitting layer 30, for example, comprises a multiple quantum well (MQW) structure. In the MQW structure, for example, a plurality of barrier layers and a plurality of well layers are stacked alternately. For example, the well layers comprise InGaAlN (indium gallium aluminum nitride). For example, the well layers comprise InGaN (indium gallium nitride).

In this specification, a stacked state (or a stacked layer) means not only a stack of layers each of which is directly connected to its adjacent layers in the stack, but also other elements may be interposed between layers of the stack layer.

The barrier layer, for example, comprises Si doped n-type AlGaN. For example, the barrier layer comprises Si doped n-type Al_{0.11}Ga_{0.89}N. A thickness of the barrier layer is, for example, more than or equal to 2 nm less than or equal to 30 nm. A thickness of one of the barrier layers which is disposed closest to the semiconductor layer 20 can be the same thickness as other barrier layers or thicker than other barrier layers or thinner than other barrier layers.

A wave length (a peak wavelength) of a light (an emitted light) which is emitted from the light emitting layer 30 is, for example, more than or equal to 210 nm and less than or equal to 700 nm. The peak wave length is, for example, more than or equal to 370 nm and less than or equal to 480 nm.

The semiconductor layer 20 includes, for example, a non-doped AlGaN spacer layer, a magnesium (Mg) doped p-type AlGaN clad layer, a Mg doped p-type GaN contact layer, and a high concentration Mg doped p-type GaN contact layer. The Mg doped p-type GaN contact layer is provided between the high concentration Mg doped p-type GaN contact layer and the light emitting layer 30. The Mg doped p-type AlGaN clad layer is provided between the Mg doped p-type GaN contact layer and the light emitting layer 3. The non-doped AlGaN spacer layer is provided between the Mg doped p-type AlGaN clad layer and the light emitting layer. For example, the semiconductor layer 20 includes non-doped Al_{0.11}Ga_{0.89}N spacer layer, Mg doped p-type Al_{0.28}Ga_{0.72}N clad layer, Mg doped p-type GaN contact layer, and high concentration Mg doped p-type GaN contact layer.

Here, in the various semiconductor layers described above, composition, composition ratio, kinds of impurities, impurity concentration and thickness are examples only. Each parameter could be changed variously.

The conductive layer 41, described above, is provided between the metal layer 51 and the second conductive portion 12. The conductive layer 41 is electrically connected to the pad electrode 44. It is preferable that a reflectivity of the conductive layer 41 is high. For example, the conductive layer 41 includes at least one of aluminum or silver. Other conductive layers may be provided between the conductive layer 41 and the second semiconductor portion 12. In the semiconductor light emitting element 1, since the conductive layer 41 is provided, a shielding film is not necessary to be provided. So, high light extraction efficiency can be obtained. A material for the conductive layer 41 may be an aluminum material which provides ohmic connectivity to the semiconductor layer 10 and high reflecting ratio.

The pad electrode 44 is provided above the metal layer 51 on a side facing the semiconductor light emitting portion 15. The pad electrode 44 and the semiconductor light emitting layer 30 do not overlap each other when they are projected on to X-Y plane. The pad electrode 44 and the semiconductor light emitting portion 15 are separated (spaced from each other) in the X-Y plane. The pad electrode 44 is, for example, a stacked electrode in which a Ti layer (for example, thickness=10 nm), a Pt layer (for example, thickness=100 nm) and an Au layer (for example, thickness=1000 nm) are stacked in this order.

A metal layer 53 which reflects light is provided in the semiconductor light emitted element 1. The metal layer 53 comprises at least one of aluminum (Al) or silver (Ag). The metal layer 53 and the semiconductor light emitting portion 15 overlap each other when they are projected onto X-Y plane (not specifically illustrated in figures). The metal layer 53 and the semiconductor light emitting portion 15 overlap each other in X-Y plane. For example, a middle part of the semiconductor light emitting portion 15 overlaps the metal layer 52 in X-Y plane and a peripheral part of the semiconductor light emitting layer 15 overlaps the metal layer 53 in X-Y plane.

A light emitted from the semiconductor light emitting portion 15 is reflected upwards by the metal layer 52, the metal layer 53, and the conductive layer 41. Thus, the light extracting efficiency may be increased, since light which would otherwise leak to the underside of the semiconductor light emitting element 1 (a side of the support substrate 64) may be decreased.

The interlayer insulating layer 80 includes a first insulating portion 81 and a second insulating portion 82. The first insulating portion 81 is provided between the metal layer 53 and the semiconductor light emitting portion 15. The second insulating layer 82 is provided between the metal layer 53 and the metal layer 51. A border of the first insulating portion 81 and the second insulating portion 82 is sometime observable and sometime unobservable, it could be both cases.

The interlayer insulating layer 80, for example, comprises a dielectric. Specifically, the interlayer insulating layer 80 could comprise silicon oxide, silicon nitride, or silicon oxynitride. It is also possible that the interlayer insulating layer 80 comprises a metal oxide which includes any one of Al, Zr, Ti, Nb and Hf. Oxides of other metals may be included in interlayer insulating layer 80.

And it is also possible that the interlayer insulating layer 80 comprises a metal nitride which includes at least any one of the materials described above or a metal oxynitride which includes at least any one of the materials described above.

An interlayer insulating layer 85 includes a first interlayer insulating portion 86, a second interlayer insulating portion 87 and a third interlayer insulating portion 88. The interlayer insulating layer 85 comprises the same material as the interlayer insulating layer 80. At least one part of the interlayer insulating layer 85 could be formed by a same process in which at least one part of the interlayer insulating layer 80 is formed.

The first interlayer insulating portion 86 is provided between the semiconductor light emitting portion 15 and the second interlayer insulating portion 87. The second interlayer insulating portion 87 is provided between the conductive layer 41 and the metal layer 51. The third interlayer insulating portion 88 is provided between the pad electrode 44 and the metal layer 51. The pad electrode 44 and the conductive layer 41 are insulated from the metal layer 51 by the interlayer insulating layer 85.

A top surface 14 of the semiconductor light emitting portion 15 includes a convex-concave portion which can limit interfacial reflections at the upper surface 14. The convex-concave portion has a plurality of convex portions 14p. It is preferable that a distance between adjacent ones of the convex portions 14p in the plurality of convex portions 14p be more than or equal to the peak wavelength of light emitted from the semiconductor emitting portion 15. Then, the light extracting efficiency may be increased.

If the distance between two of the plurality of convex portions 14p which are adjacent is shorter than the wavelength, the emitted light which is incident to the convex-concave portion may show a behavior which can be explained by a field of the wave-optics for scattering and diffraction at a border of the convex-concave portion.

A planar shape of the convex portions 14p is, for example, hexagon. For example, the convex-concave portion is formed by an anisotropic etching process in which the semiconductor layer 10 is etched by potassium hydroxide (KOH) solution. Then, the emitted light which emitted from the light emitting layer 30 may be reflected by Lambert reflection at an interface between the semiconductor layer 10 and outside.

Also, the convex-concave portion may be formed by dry etching process which uses a mask. In this process, since s shape of the convex-concave portion can be formed to substantially match a particular design, reproducibility of the shapes of the protrusions in the convex-concave portion may be improved and the light extracting efficiency may be improved.

The semiconductor light emitting element 1 may further include a side surface of the semiconductor layer 10, a side surface of the light emitting layer 30 and an insulating layer (not specifically illustrated in figures) which covers the side surface of the semiconductor layer 20. The insulating layer, for example, comprises a same material as the first insulating portion 81. For example, the insulating layer includes SiO2. The insulating layer has a function of a protection layer for the semiconductor light emitting portion 15. Thus, a deterioration and a leak current of the semiconductor light emitting portion 15 may be restrained.

The semiconductor light emitting element 1 may further comprise a housing which covers the semiconductor light emitting portion 15. The housing, for example, comprises a resin. The housing may include a wave length converting material. The wave length converting material absorbs a part of the emitted light from the semiconductor light emitting element 1. Then, the wave length converting material emits a light which has wavelength that is different from the wavelength of the emitted light from the light emitting layer 30. The wave length converting material, for example, comprises a phosphor.

By applying a voltage between the back surface electrode 65 and pad electrode 44, a voltage is applied to the light emitting layer 30 through the metal layer 51, metal layer 52 and the semiconductor layer 20 or through the conductive layer 41 and the semiconductor layer 10.

A first part of the emitted light is emitted upward and is emitted out of the semiconductor light emitting element 1. On the other hand, a second part of the emitted light is reflected by metal layer 52 upward and emitted out of the semiconductor light emitting element 1.

Next, an example of a method of manufacturing the semiconductor light emitting element 1 will be described.

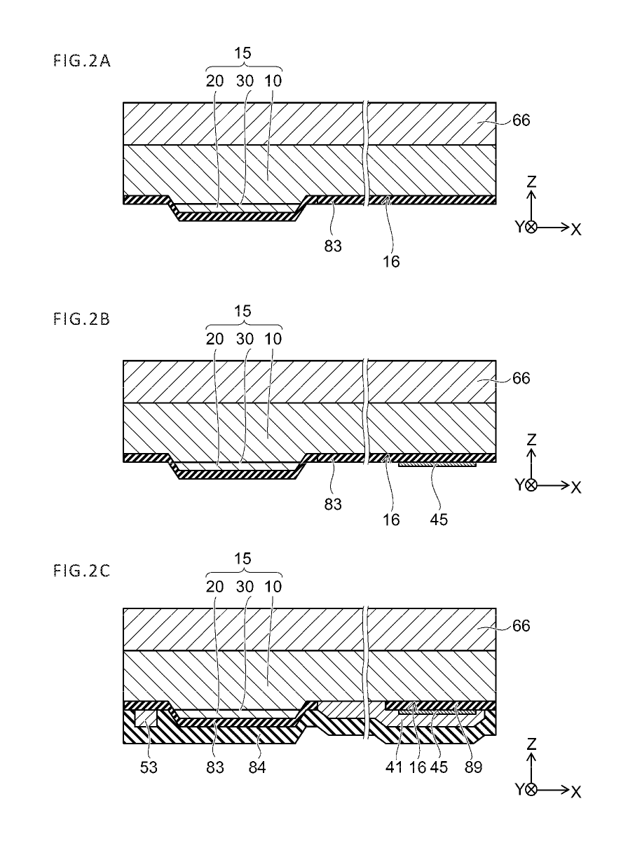

FIGS. 2A to 4B are main parts of cross-sectional views schematically illustrating a method of manufacturing the semiconductor light emitting element according to this embodiment. FIGS. 2A to 4B are cross-sectional views taken at line A1-A2 of FIG. 1B.

For example, as illustrated in FIG. 2A, the semiconductor layer 10, the light emitting layer 30 and the semiconductor layer 20 are grown by an epitaxial process in this order on a growth substrate 66. After that, a part of the semiconductor layer 20 and a part of the light emitting layer 30 are removed by etching. A stacked layer, which includes the semiconductor layer 10, the light emitting layer 30 and the semiconductor layer 20, is formed.

Next, the insulating layer 83 is formed over under surface 16 of the semiconductor layer 10 to cover the under surface, and indeed cover the light emitting layer 30 and semiconductor layer 20.

Next, as illustrated in FIG. 2B, the protecting layer 45 is formed to cover the insulating layer 83. The protecting layer 45 includes metal.

Next, as illustrated in FIG. 2C, the insulating layer 83 is removed selectively. Next, the conductive layer 41 is formed to electrically connect to the under surface 16 in a portion where the light emitting layer 30 is not provided and covers the protecting layer 45. The insulating layer 89 is formed between the conductive layer 41 and the semiconductor layer 10. A material of the insulating layer 89 is same as the material of the insulating layer 83. Then, the metal layer 53 which covers the insulating layer 83 selectively is formed. After that, the insulating layer 84 which covers the insulating layer 83, conductive layer 41, the insulating layer 89 and the metal layer 53 is formed.

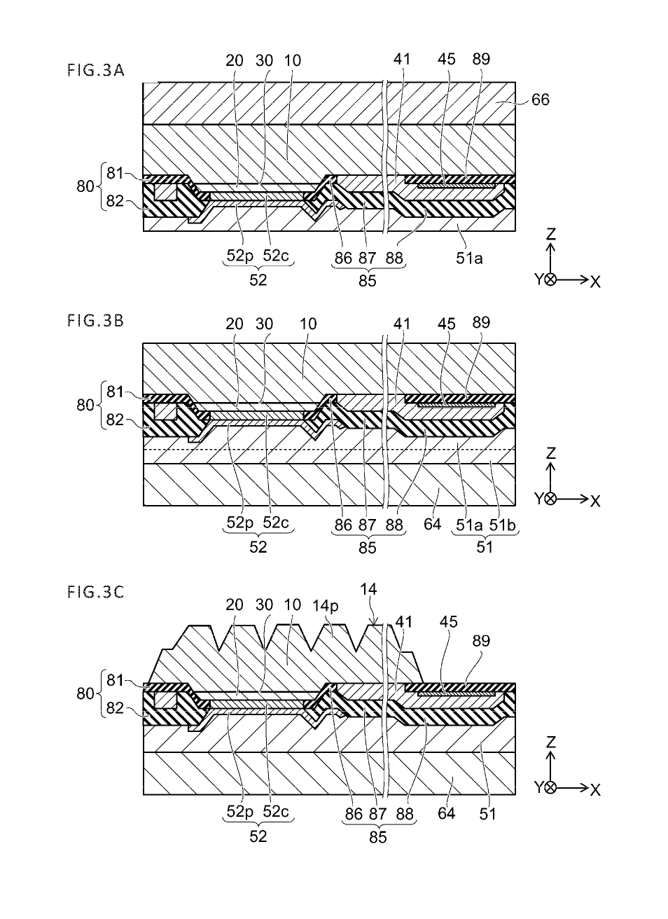

Next, as illustrated in FIG. 3A, the insulating layer 83 which connects to the semiconductor layer 20 is removed selectively. And the insulating layer 84 which connects to the insulating layer 83 which connects to the semiconductor layer 20 is removed selectively. Then, the interlayer insulating layer 80 and interlayer insulating layer 85 are formed. After that, the metal layer 52 which electrically connects to the semiconductor layer 20 is formed. Next, the metal layer 51 which covers the metal layer 52, the interlayer insulating layer 80 and interlayer insulating layer 85 is formed.

Next, as illustrated in FIG. 3B, the support substrate 64 in which the metal layer 51b is formed is connected to the metal layer 51a. For example, the metal layer 51 is formed by connecting the metal layer 51a and the metal layer 51b. After that, the growth substrate 66 is removed from the semiconductor substrate 10.

Next, as illustrating in FIG. 3C, a part of semiconductor layer 10 is removed. Then, the insulating layer 89 on the protecting layer 45 is exposed. The conductive layer 41 thus extends from the back surface 16 of the semiconductor layer 10 to outside of the semiconductor layer 10. And the convex portion 14p is formed on the upper surface 14 of the semiconductor layer 10.

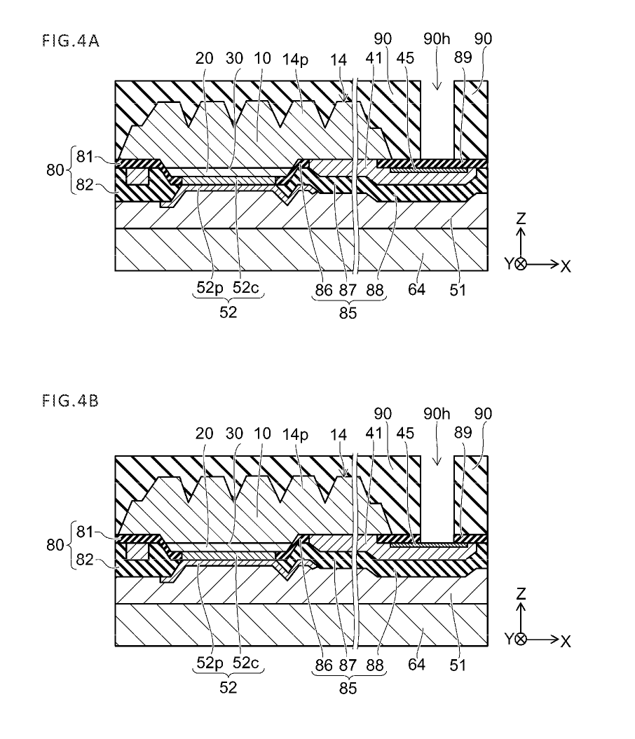

Next, as illustrated in FIG. 4A, a mask layer 90 which covers the semiconductor layer 10 and the insulating layer 89 selectively is formed. The mask layer 90, for example, includes a resist (e.g., photoresist). The mask layer 90 has an opening 90h formed therein. The insulating layer 89 is exposed at the opening 90h.

Next, as illustrated in FIG. 4B, the insulating layer 89 that exposed by the mask layer 90 is etched by an aqueous buffered hydrofluoric acid solution (BHF solution). Then, the protecting layer 45 is exposed from the insulating layer 89. After that, the resist is removed. It is possible to clean the surface of the protecting layer 45 in an etching gas in a dry wash process.

After that, as illustrated in FIG. 1A, the pad electrode 44 which is electrically connected to the protecting layer 45 is formed. And, the back surface electrode 65 which is electrically connected to the support substrate 64 is formed.

Hereinafter, a method of manufacturing the protecting layer 45 is described in more detail.

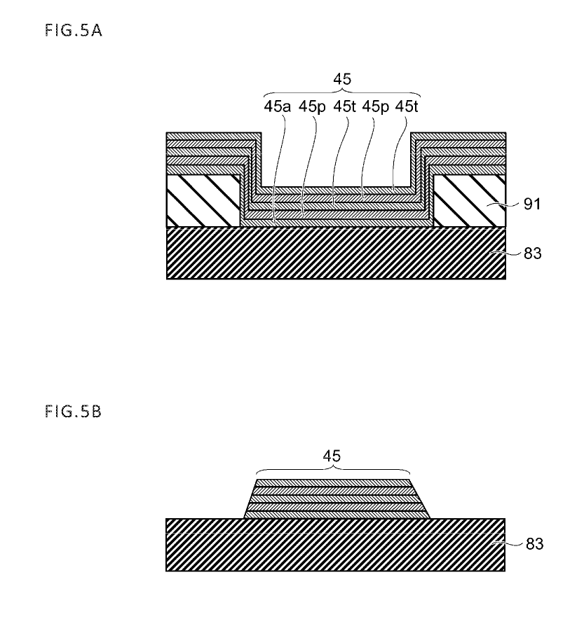

FIGS. 5A and 5B are cross-sectional views schematically illustrating one example of a method of manufacturing the protecting layer.

For example, as illustrated in FIG. 5A, a mask layer 91 is formed on the insulating layer 83 by photolithography and etching. The mask layer 91, for example, includes a resist material. Next, a stacked layer in which Pt layers 45p, Ti layers 45t are stacked in alternation on an Au layer 45a is formed on insulating layer 83 and the mask layer 91. This stacked layer can be formed by vacuum depositing, sputtering and/or CVD, etc.

Next, as illustrated in FIG. 5B, the mask layer 91 and stacked layer connected to the mask layer 91 are removed (metal lift-off process). Thus, the protecting layer 45 is formed on the insulating layer 83 selectively.

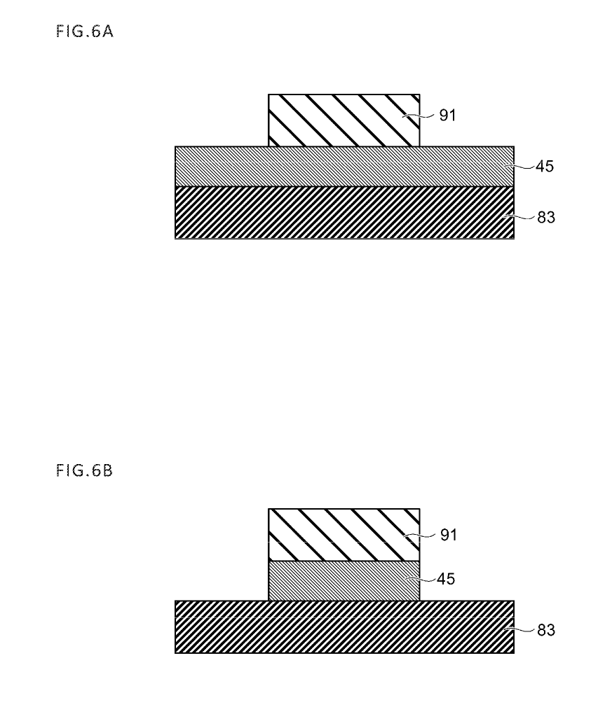

FIGS. 6A and 6B are cross-sectional views schematically illustrating a second example of a method of manufacturing the protecting layer 45.

For example, when the protecting layer 45 includes a TiN, as illustrated in FIG. 6A, the protecting layer 45 is formed on the insulating layer 83. Next, the mask layer 91 is formed on the protecting layer 45 by photolithography and etching.

Next, as illustrated in FIG. 6B, the protecting layer 45 which is exposed by the mask layer 91 is removed by RIE (Reactive Ion Etching). After that, the mask layer 91 is removed. Thus, the protecting layer 45 is formed on the insulating layer 83 selectively.

In the process which is illustrated in FIG. 4B, the protecting layer 45 is exposed from the insulating layer 89. The conductive layer 41 is not exposed from the insulating layer 89. That is, the conductive layer 41 is covered by the protecting layer 45.

For example, if the conductive layer 41 includes Al and the protecting layer 45 is not provided, in the process of FIG. 4B, the conductive layer 41 could be exposed to the air atmosphere. In this case, natural oxide film (for example, AlOx) could be formed on the surface of the conduct layer 41. If the conductive layer 41 is exposed to the aqueous hydrofluoric acid solution (BHF solution) or the gas for the dry process, the surface of the conductive layer 41 could be corroded. Then, the electrical resistivity between the conductive layer 41 and pad electrode 44 could be increased, and also, the reflectivity of the conductive layer 41 could be decreased.

In contrast, according to this embodiment, in the process according to the FIG. 4B, the conductive layer 41 is covered by the protecting layer 45. Therefore, the natural oxide film is not formed on the conductive layer 41. Then, the increase in the electrical resistivity between the conductive layer 41 and the pad electrode 44 may be smaller in this embodiment than the increase in the electrical resistivity by the natural oxide film. Therefore, a forward voltage (Vf) may not be increased. Also, the conductive layer 41 is not exposed to the aqueous hydrofluoric acid solution (BHF solution) or the gas for the dry process. Therefore, the conductive layer 41 may become hard to be corroded and the reflectivity may not be decreased.

That is, according to the semiconductor light emitting element described in this embodiment, a decrease of electrical efficiency may be suppressed. According to this embodiment, the electrical efficiency may become stable. Here, for example, the electrical efficiency is defined by a ratio of a total luminous flux which the semiconductor light emitting element 1 emits to outside to an electric power which is imposed on the semiconductor light emitting element 1. Or, it is also possible that the electrical efficiency is defined by a ratio of a luminous flux which the semiconductor light emitting element 1 emits to specific direction to the electric power which is imposed on the semiconductor light emitting element 1.

Indeed, since the corrosion of the conductive layer 41 by the natural oxide is suppressed, a yield on the products may be improved and reliability may be increased.

The efficient operation of this embodiment is described following in detail.

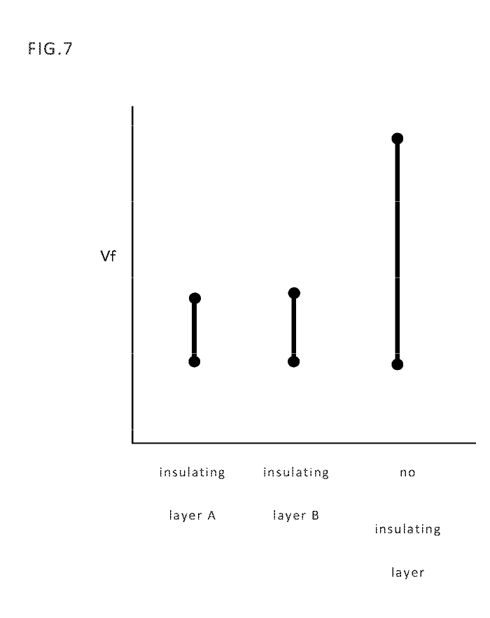

FIG. 7 is a graph illustrating a variation of an operating voltage (Vf) of the semiconductor light emitting layer according to an embodiment.

A protecting layer A is a protecting layer 45 that includes the stacked layer which includes the Ti layer 45t, Pt layer 45p and Au layer 45a. A protecting layer B is a protecting layer 45 that includes a single layer of TiN. In addition, in FIG. 7, an example in which the protecting layer 45 is not provided is illustrated.

As illustrated in FIG. 7, the variation of an operating voltage (Vf) of the semiconductor light emitting element which includes the protecting layer A or the protecting layer B is one third of that of the semiconductor light emitting element which does not include the protecting layer A or the protecting layer B. That is, according to the semiconductor light emitting element 1 of this embodiment, the variation of an operating voltage (Vf) may be decreased much.

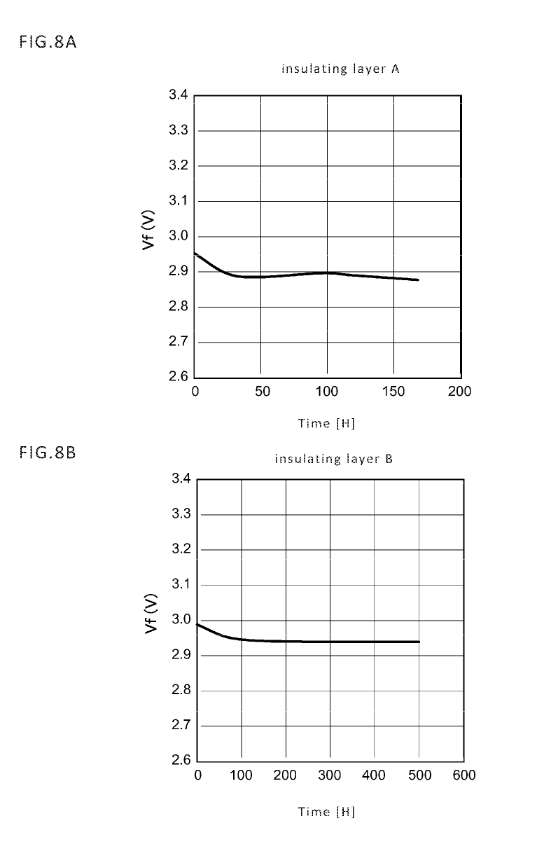

FIGS. 8A and 8B are a graph illustrating a time series change of the operating voltage (Vf) of the semiconductor light emitting layer according to an embodiment.

Hereinafter, the semiconductor light emitting element of this embodiment is provided in 55° C. atmosphere and 1500 mA current flows. A horizontal axis of the FIG. 8 is test time (forward time)/time (h). A vertical axis is the forward voltage (Vf).

As illustrated FIG. 8A, the forward voltage (Vf) of the semiconductor light emitting device which includes the protecting layer A is stable for more than 170 hours.

As illustrated in FIG. 8B, the forward voltage (Vf) of the semiconductor light emitting device which includes the protecting layer B is stable for more than 500 hours.

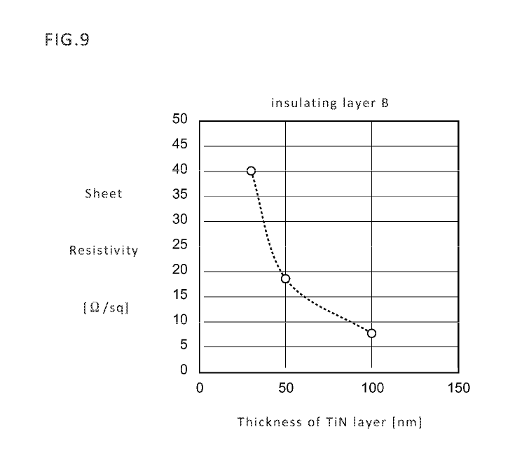

FIG. 9 is a graph illustrating a relationship between a sheet resistivity of the protecting layer and a thickness of the protecting layer of the semiconductor light emitting layer according to this embodiment.

Hereinafter, the protecting layer 45 is the protecting layer B. With an increase of a thickness of the TiN layer, the sheet resistivity of the protecting layer (the protecting layer B) decreases. For example, to obtain the high electric efficiency of the semiconductor light emitting element, the thickness of the protecting layer 45 (the protecting layer B) is preferably more than or equal to 50 nm and less than or equal to 100 nm.

If the protecting layer 45 is, for example, the stacked layer in which an Au layer 45a, a Pt layer 45p and the Ti layer 45t are stacked in this order or the stacked layer in which an Au layer 45a, a Pt layer 45p, the Ti layer 45t, the Pt layer 45p and the Ti layer 45t are stacked in this order, the efficient is described as follows.

Adhesion between the protecting layer 45 and the interlayer insulating layer which connects to the protecting layer 45 may be preferable.

In the disclosure, “nitride semiconductor” means semiconductor material which includes BxInyAlzGal-x-y-zN (0≦≦1, 0≦y<≦1, 0≦z≦1, x+y+z≦1), x, y and z can be combined within the chemical formula described above. Also, “nitride semiconductor” includes group V elements besides a nitride, doping elements and elements which are included unintentionally.

In the disclosure, “perpendicular” and “parallel” means not only exactly perpendicular and parallel but also substantially so, such that the terms, includes normal and expected variations within tolerances in the manufacturing process.

“On” includes both in meaning of directly on (directly contacting, directly connected, etc.) and indirectly on such that other layers or elements may be interposed.

The present disclosure is not limited to the specific examples and embodiments described above. Those skilled in the art can appropriately select a specific configuration of each of the components and those layouts, the materials, the conditions, the shapes and the sizes, thereby similarly implementing the present disclosure, and these modifications are included in the scope of the present disclosure as long as it is possible to achieve the same effects as those of the present disclosure.

Furthermore, modifications which are obtained by combining the components of two or more of the specific examples are also included in the scope of the present disclosure. Moreover, all of semiconductor light emitting element and method of manufacturing them obtainable by appropriate design modifications by those skilled in the art based on the semiconductor light emitting element and the methods of manufacturing them described above as an embodiment of the disclosure are also included in the scope of the disclosure as long as the modifications include the gist of the present disclosure.

Various other variations and modifications can be conceived by those skilled in the art within the spirit of the disclosure, and it is understood that such variations and modifications are also encompassed within the scope of the disclosure.

While certain embodiments have been described, these embodiments have been presented byway of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor light emitting element, comprising:
a first semiconductor layer of a first conductivity type and having an upper surface side and a under surface side, a first portion of the first semiconductor layer being adjacent to a second portion of the first semiconductor layer in a first direction;
a light emitting layer adjacent to the first portion on the under surface side;
a second semiconductor layer of a second conductivity type that is opposite to the first conductivity type, the light emitting layer being between the second semiconductor layer and the first portion;
a first conductive layer electrically contacting the second portion of the first semiconductor layer on the under surface side, the first conductive layer extending beyond an outer edge of the first semiconductor layer in the first direction;
a protecting layer on an upper surface side of the first conductive layer, the protecting layer comprising a metal; and
a pad electrode on the upper surface side of the first conductive layer and electrically connected to the first conductive layer through the protecting layer.

2. The semiconductor light emitting element of claim 1, wherein the protecting layer includes at least one metal selected from a group consisting of nickel (Ni), gold (Au), titanium (Ti), and platinum (Pt).

3. The semiconductor light emitting element of claim 1, wherein the protecting layer is a stacked layer including a first stacked layer comprising nickel (Ni) on a second stacked layer comprising gold (Au).

4. The semiconductor light emitting element of claim 1, wherein the protecting layer is a stacked layer including a first stacked layer comprising platinum (Pt) on a second stacked layer comprising titanium (Ti), the first and second stacked layers being stacked on a third stacked layer comprising gold (Au).

5. The semiconductor light emitting element of claim 1, wherein the protecting layer comprises a metal nitride or a metal oxide.

6. The semiconductor light emitting element of claim 1, wherein the protecting layer comprises titanium nitride (TiN).

7. The semiconductor light emitting element of claim 6, wherein the protecting layer is greater than or equal to 50 nm in thickness.

8. The semiconductor light emitting element of claim 1, wherein the protecting layer comprises a metal nitride and is greater than or equal to 50 nm in thickness.

9. The semiconductor light emitting element of claim 1, wherein the protecting layer is greater than or equal to 50 nm in thickness.

10. The semiconductor light emitting element of claim 1, wherein the first conductive layer is one of a metallic aluminum layer or a metallic silver layer.

11. The semiconductor light emitting element of claim 1, wherein the first conductive layer comprises at least one of aluminum (Al) and silver (Ag).

12. The semiconductor light emitting element of claim 1, further comprising:
an insulating layer on a first portion of the protecting layer, the first portion of the protecting layer being between the insulating layer and the first conductive layer, the pad electrode being connected to a second portion of the protecting layer through an opening in the insulating layer.

13. The semiconductor light emitting element of claim 12, wherein the protecting layer includes at least one metal selected from a group consisting of nickel (Ni), gold (Au), titanium (Ti), and platinum (Pt).

14. The semiconductor light emitting element of claim 12, wherein the protecting layer comprises a metal nitride or a metal oxide.

15. The semiconductor light emitting element of claim 12, wherein the first conductive layer comprises at least one of aluminum (Al) and silver (Ag).

16. A method of manufacturing a light emitting element, the method comprising:
forming a stacked layer that includes:
a first semiconductor layer of a first conductivity type,
a second semiconductor layer of a second conductivity type that is opposite to the first conductivity type, and
a light emitting layer between the second semiconductor layer and a first portion of the first semiconductor layer;
forming an insulating layer that covers an under surface side of the first semiconductor layer, the light emitting layer being on the under surface side of the first semiconductor layer;
forming a protecting layer comprising a metal on a portion of the insulating layer, the protecting layer being on an under surface side of the insulating layer opposite the under surface side of the first semiconductor layer;
forming a first conductive layer electrically contacting a second portion of the first semiconductor layer on the under surface side of the first semiconductor layer and covering the protecting layer, the second portion being adjacent to the first portion;
exposing an upper surface side of the insulating layer by removing a part of the first semiconductor layer, then removing a portion of the insulating layer to expose a portion of the protecting layer; and
forming a pad electrode on the portion of the protecting layer, the pad electrode being electrically connected to the first conductive layer by the protecting layer.

17. The method of claim 16, further comprising:
forming a convex-concave portion on an upper surface side of the first semiconductor layer opposite the under surface of the first semiconductor layer.

18. The method of claim 16, wherein the protective layer is a conductive metal nitride or a conductive metal oxide.

19. The method of claim 16, wherein the protective layer comprises a plurality of metallic layers in a stacked arrangement.

20. A semiconductor light emitting element, comprising:
a support substrate having an upper surface and a back surface opposite the upper surface;
a back surface electrode on the back surface of the support substrate;
a first metal layer on the upper surface of the support substrate;
a second metal layer on a portion of the first metal layer;
a semiconductor light emitting portion on the upper surface of the support substrate, the first and second metal layers being between the semiconductor light emitting portion and the support substrate, the semiconductor light emitting portion having a light emitting layer disposed between a second conductivity type layer and a first portion of a first conductivity type semiconductor layer, the second metal layer electrically contacting the second conductivity type layer;
an insulating layer on the first metal layer, the second metal layer extending through an opening in the insulating layer between the first metal layer and the semiconductor light emitting portion;
a third metal layer on a portion of an upper surface of the insulating layer, the third metal layer contacting a under surface side of the first conductivity type semiconductor layer and extending beyond an outer edge of the semiconductor light emitting portion;
a protective layer comprising a metal on a portion of an upper surface of the third metal layer, the portion being beyond the outer edge of the semiconductor light emitting portion;
an insulating material on a first portion of an upper surface of the protective layer;
a pad electrode on a second portion of the upper surface of the protective layer, the pad electrode and the third metal layer being electrically connected with the protective layer.
